(19) United States
(12) Patent Application Publication
(10) Pub. No.: US 2021/0257814 A1
(43) Pub. Date: Aug. 19, 2021

(54) OPTICAL MODULE

(71) Applicant: SUMITOMO ELECTRIC INDUSTRIES, LTD., Osaka-shi, Osaka (JP)

(72) Inventor: Yohei ENYA, Osaka-shi (JP)

(73) Assignee: SUMITOMO ELECTRIC INDUSTRIES, LTD., Osaka-shi, Osaka (JP)

(21) Appl. No.: 17/251,844

(22) PCT Filed: Jun. 17, 2019
(86) PCT No.: PCT/JP2019/023831

§ 371 Date: Dec. 14, 2020

(30) Foreign Application Priority Data
Jun. 29, 2018 (JP) 2018-124791

(51) Int. Cl. H01S 5/40; G02B 27/28; H01S 5/02212; H01S 5/02255

(52) U.S. Cl. CPC H01S 5/4012; G02B 27/288; G02B 27/0101; H01S 5/4093; H01S 5/02255; H01S 5/02212

(57) ABSTRACT

An optical module includes a first laser diode emitting a first light, a second laser diode emitting a second light of a different wavelength from the first light, and a filter multiplexing the first and the second light. The filter has a polarization selectivity for selectively transmitting light of a linearly polarized light component in a particular direction included in the first light, a wavelength selectivity for transmitting the first light and reflecting the second light.

### TECHNICAL FIELD

This application claims priority to Japanese Patent Application No. 2018-124791, filed Jun. 29, 2018, the contents of which are incorporated herein by reference in its entirety.

### BACKGROUND ART

An optical module including a light-emitting section in which light from a plurality of semiconductor light-emitting devices is multiplexed and emitted, and a scanning section in which light from the light-emitting section is scanned (see, for example, PTL1-3) is known. Such an optical module can draw characters and figures by scanning light from the light emitting unit along a desired path.

### CITATION LIST

### Patent Literature

PTL1: Japanese Unexamined Patent Application Publication No. 2014-186068
PTL2: Japanese Unexamined Patent Application Publication No. 2014-56199
PTL3: WO 2007/120831

### SUMMARY OF INVENTION

An optical module of the present disclosure includes a first laser diode emitting a first light, a second laser diode emitting a second light of a different wavelength from the first light, a filter multiplexing the first light and the second light. The filter has a polarization selectivity for selectively transmitting a linearly polarized light component of the first light in a particular direction and a wavelength selectivity for transmitting the first light and reflecting the second light.

### BRIEF DESCRIPTION OF DRAWINGS

FIG. 1 is an exterior view of the structure of an optical module in the first embodiment.

FIG. 2 is a view corresponding to the state in which the cap is removed in the optical module shown in FIG. 1.

FIG. 3 is a top view of the optical module with the cap shown in FIG. 2 removed.

FIG. 4 is a side view of the optical module with the cap shown in FIG. 3 removed.

FIG. 5 is an enlarged cross-sectional view of the second filter in the first embodiment.

FIG. 6 is a simplified view of a laser diode, a lens and a filter in the optical module in the first embodiment.

FIG. 7 is a schematic view showing an example of a HUD system installed in an automobile.

FIG. 8 is an enlarged cross-sectional view of the second filter in the second embodiment.

FIG. 9 is a simplified view of a laser diode, a lens and a filter arranged in an optical module in the third embodiment.

FIG. 10 is a simplified view of a laser diode, a lens and a filter arranged in an optical module in the fourth embodiment.

### DESCRIPTION OF EMBODIMENTS

An optical module draws characters and figures by reflecting and scanning light from a mirror that rocks periodically at high speed in one direction and in a direction perpendicular to one direction. A polarization angle of light emitted from a laser diode as a semiconductor light-emitting device may change depending on its output. When the polarization angle is changed, a ratio of linearly polarized light components in a particular direction to linearly polarized light components in other directions is changed for the light emitted from the laser diode. Then, it may not be possible to obtain desired brightness or color tone of the multiplexing light. A size of the optical module has to be reduced in consideration of its use in vehicles.

### DESCRIPTION OF EMBODIMENTS OF PRESENT DISCLOSURE

First, the embodiments of the present disclosure are listed and described. An optical module includes a first laser diode emitting a first light, a second laser diode emitting a second light of a different wavelength from the first light, a filter multiplexing the first light and the second light. The filter has a polarization selectivity for selectively transmitting light of a linearly polarized light component in a particular direction included in the first light.

With the above optical module, miniaturization is achieved. The above optical module can precisely adjust the brightness and color tone of the multiplexing light.

The filter provided in such an optical module has a wavelength selectivity that transmits the first light and reflects the second light. By arranging the first laser diode, the second laser diode and the filter so that the light path of the first light passing through the filter and the second light reflecting off the filter are the same, the first light and the second light can be multiplexed. The filter has the polarization selectivity that selectively transmits light of the linearly polarized light component in a particular direction contained in the first light. Thus, the intensity of the first light can be adjusted by reducing the effect of the linearly polarized light component of the first light emitted from the filter other than in a particular direction. Therefore, even if the polarization angle of the first light changes, the intensity ratio of the first light to the second light in the multiplexing light can be adjusted appropriately. Also, there is no need for a new polarizer in the optical module because the filter has the polarization selectivity that selectively transmits the linearly polarized light component of the first light in a particular direction. With such an optical module, miniaturization can be achieved. The above optical module can precisely adjust the brightness and color tone of the multiplexing light. For polarization selectivity, selective transmission means that the light transmittance of the linearly polarized light component in the specific direction included in the first light is 90% or more, and the light transmittance of the linearly polarized light component other than the specific direction included in the first light is 10% or less. An extinction ratio for a filter with such a polarization selectivity is 1:9 or more. For example, it is effective when used as a head-up display (HUD) for vehicles. For polarization selectivity, it is preferable that the light transmittance of the linearly polarized light component in the specific direction included in the first light is 95% or more, and the light transmittance of the linearly polarized light component other than the specific direction included in the first light is 5% or less. It is even more desirable that the transmittance of the linearly polarized light component in a particular direction included in the first light is 98% or more, and that the transmittance of the linearly polarized light component in a direction other than a particular direction included in the first light is 2% or less.

In the above optical module, the filter may include a first face in which the first light enters, a second face in which the first light incident from the first face emits and the second light reflects, a first dielectric multilayer film constituting the first face, and a second dielectric multilayer film constituting the second face. The first dielectric multilayer film may have polarization selectivity that selectively transmits light of linearly polarized light components in a particular direction in the first light. The second dielectric multilayer film may have a wavelength selectivity that reflects the second light. Such a filter can reduce the difference between the thickness of the dielectric multilayer film constituting the first face and the thickness of the dielectric multilayer film constituting the second face. Thus, the warping of the filter based on the difference in the thickness of the dielectric multilayer film can be reduced. Therefore, the brightness and color tone of the multiplexing light can be adjusted more accurately.

In the above optical module, the filter may include a first face wherein the first light enters, a second face wherein the first light incident from the first face emits and the second light reflects, and a second dielectric multilayer film constituting the second face. The second dielectric multilayer film may have a polarization selectivity that selectively transmits the linearly polarized light component of the first light in a particular direction and a wavelength selectivity that reflects the second light. Such a filter can reduce the total deposition time when forming the first dielectric multilayer film and the second dielectric multilayer film during the manufacturing of the filter because the second dielectric multilayer film constituting the second face has wavelength selectivity and polarization selectivity.

In the above optical module, an angle of incidence of the first light to the first face may be from 10° to 60°. In this range of incidence angles, there is a large difference between the reflectance of the linearly polarized light component in a particular direction and the reflectance of the linearly polarized light component in other directions. Therefore, it is relatively easy to form films with polarization selectivity. Therefore, a filter with polarization selectivity can be produced efficiently. It is further preferred that the angle of incidence of the first light to the first face is from 35° to 55°.

In the above optical module, the filter may have transmittance of 90% or more of a p-polarized light component in the first light and transmittance of 10% or less of a s-polarized light component in the first light.

In this way, the linearly polarized light component of the first light in a particular direction can be used as the light of the p-polarized light component to reduce optical loss and to efficiently adjust the light to be multiplexed.

In the above optical module, the filter may reflect 90% or more of the second light emitted from the second laser diode. In this case, the second light can be used efficiently.

The above optical module may further include a light-receiving device receiving the light that is multiplexed by the filter. The light-receiving device will receive the light multiplexed by the filter, so that for the first light, it will receive light of a linearly polarized light component in a specific direction that is selectively transmitted. Therefore, the light-receiving device can properly adjust the intensity ratio of the multiplexed light when feeding back to the output of the laser diode based on the intensity of the light received by the light-receiving device. Therefore, it is easy to precisely adjust the brightness and color tone of the multiplexing light.

The above optical module may further include a lens converting spot size of at least one of the first light and the second light. In this case, light with a desired spot size can be emitted from the optical module.

The above optical module may further include a protective member surrounding the first laser diode, the second laser diode and the filter and sealing the first laser diode, the second laser diode and the filter. In this case, the first laser diode, the second laser diode and the filter which are configurations of the optical module can be effectively protected from the external environment, thus ensuring a high level of reliability.

The above optical module may further include a third laser diode emitting blue light. The first laser diode may emit red light and the second laser diode may emit green light. In this way, these lights can be multiplexed to form a light of the desired color. In particular, red light has a large change in polarization angle with respect to the output, which reduces the effect of the change in polarization angle on the output of light in the optical module and allows the brightness and color tone of the multiplexing light to be adjusted precisely.

### Details of the Embodiment

Embodiments of an optical module according to the present disclosure will now be described with reference to the drawings. In the following drawings, the same or equivalent parts of the drawings are given the same reference numbers and the description is not repeated.

### First Embodiment

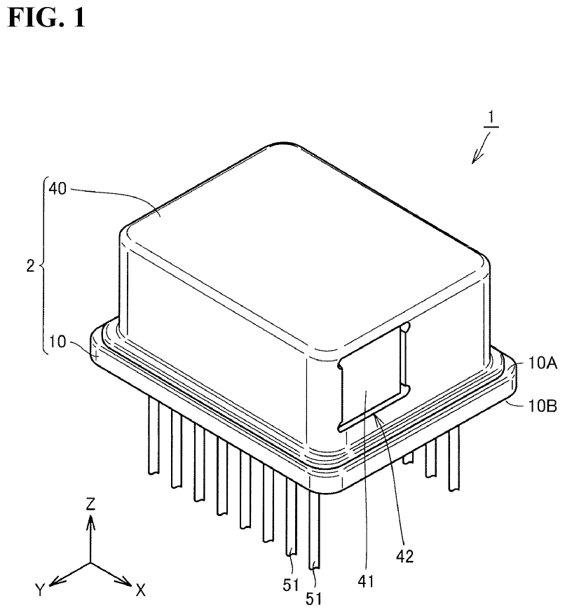

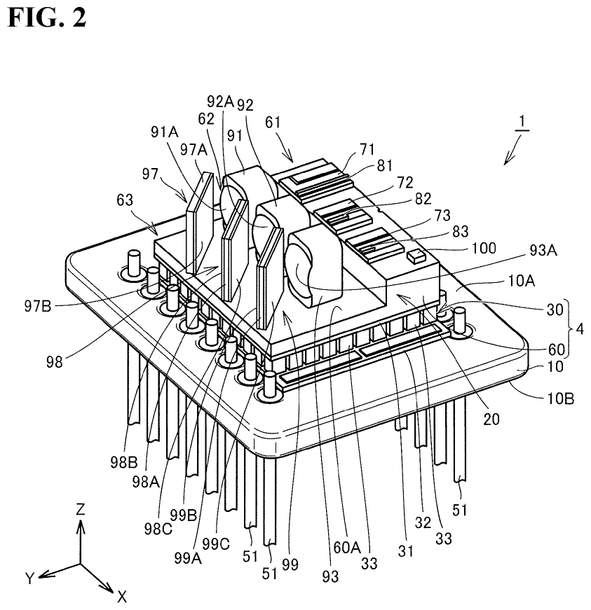

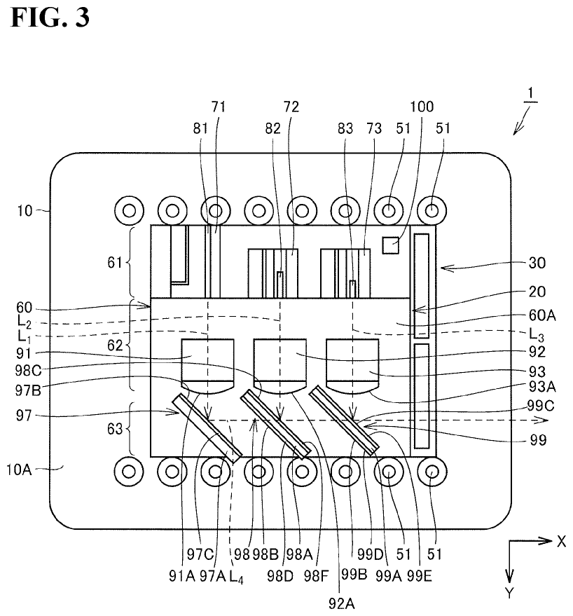

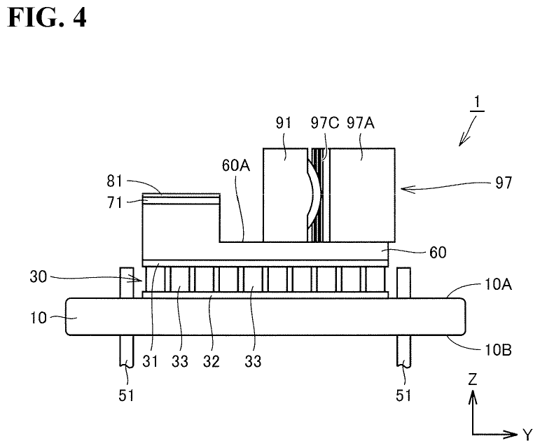

First, the first embodiment is described with reference to FIG. 1 to FIG. 4. FIG. 1 and FIG. 2 are an exterior view of the structure of an optical module in the first embodiment. FIG. 2 is a view corresponding to the state in which the cap is removed in the optical module shown in FIG. 1. FIG. 3 is a top view of the optical module with the cap shown in FIG. 2 removed. In other words, FIG. 3 is a view of the optical module along the Z-axis with the cap shown in FIG. 2 removed. FIG. 4 shows a side view of the optical module with the cap removed as shown in FIG. 3. FIG. 4 is a view from the X-axis direction. In FIG. 3, the light path is shown as a dashed line.

Referring to FIG. 1 to FIG. 4, an optical module 1 in the present embodiment includes a light-forming portion 20, which forms light, and a protective member 2, which surrounds light-forming portion 20 and seals light-forming portion 20. Protective member 2 includes a base portion 10 as a base body and a cap 40, which is a lid portion welded to base portion 10. Light-forming portion 20 is hermetically sealed by protective member 2. Base portion 10 has a flat-plate shape. Light-forming portion 20 includes a base member 4, a red laser diode 81, a green laser diode 82, a blue laser diode 83, a first lens 91, a second lens 92, a third lens 93, a first filter 97, a second filter 98, and a third filter 99. Light-forming portion 20 is placed on one main surface 10A of base portion 10. A cap 40 is placed in contact on one main surface 10A of base portion 10 so as to cover light-forming portion 20. A plurality of lead pins 51 are installed in base portion 10 so that they penetrate from the other main surface 10B side of base portion 10 to one main surface 10A side and project on both sides of one main surface 10A side and the other main surface 10B side. The space enclosed by base portion 10 and cap 40 is filled with a gas from which moisture has been reduced (removed), for example dry air. An emission window 42 is formed in cap 40. Emission window 42 is fitted with, for example, a glass member 41 of parallel flat-plate shape. In the present embodiment, protective member 2 is an airtight member that makes the interior airtight. This allows each component included in light-forming portion 20 to be effectively protected from the external environment and ensures a high reliability.

The base member 4 includes an electronic temperature control module 30 and a laser diode base 60. Electronic temperature control module 30 includes a heat absorption plate 31, a heat dissipation plate 32 and a semiconductor pillar 33. Heat absorption plate 31 and heat dissipation plate 32 consist of, for example, alumina. Electronic temperature control module 30 is disposed between base portion 10 and laser diode base 60. As heat dissipation plate 32 contacts one main surface 10A of base portion 10, electronic temperature control module 30 is placed on one main surface 10A of base portion 10. Heat absorption plate 31 is placed in contact with laser diode base 60. Electronic temperature control module 30 is a Peltier module (Peltier device) which is an electronic cooling module. By applying current to electronic temperature control module 30, the heat of laser diode base 60 in contact with heat absorption plate 31 is transferred to base portion 10, and laser diode base 60 is cooled. Electronic temperature control module 30 controls the temperature of red laser diode 81, green laser diode 82, and blue laser diode 83 based on the temperature detected by a thermistor 100 disposed on a chip mount region 61, as described below.

Laser diode base 60 has a plate-like shape. Laser diode base 60 has one main surface 60A having a rectangular shape (square shape) as viewed from the top surface. One main surface 60A of laser diode base 60 includes chip mount region 61, a lens mount region 62, and a filter mount region 63. Chip mount region 61 is formed in a region including one side of one main surface 60A, along one side. Lens mount region 62 is located adjacent to and along chip mount region 61. Filter mount region 63 is located in a region including the other sides facing the above one side of one main surface 60A and along other side. Chip mount region 61, lens mount region 62 and filter mount region 63 are parallel to each other.

The thickness of laser diode base 60 in lens mount region 62 is equal to the thickness of laser diode base 60 in filter mount region 63. Lens mount region 62 and filter mount region 63 are included in the same plane. The thickness of laser diode base 60 in chip mount region 61 is greater than lens mount region 62 and filter mount region 63. As a result, the height of chip mount region 61 (height with respect to lens mount region 62, i.e., the height in the direction perpendicular to lens mount region 62) is higher than lens mount region 62 and filter mount region 63.

On chip mount region 61, a first sub-mount 71, a second sub-mount 72 and a third sub-mount 73 of flat-plate shape are arranged in the X-axis direction. Second sub-mount 72 is located between first sub-mount 71 and third sub-mount 73. On first sub-mount 71, red laser diode 81 as the first laser diode is disposed. On second sub-mount 72, green laser diode 82 as the second laser diode is disposed. On third sub-mount 73, blue laser diode 83 as the third laser diode is disposed. The height of the optical axis of red laser diode 81, green laser diode 82 and blue laser diode 83 (the distance between the reference surface and the optical axis if lens mount region 62 of one main surface 60A is the reference surface; the distance between the reference surface and the reference surface in the Z-axis direction) is adjusted and matched by first sub-mount 71, second sub-mount 72 and third sub-mount 73. On chip mount region 61, thermistor 100, which detects the temperature of laser diode base 60, is disposed at a distance in the X-axis direction from third sub-mount 73.

First lens 91, second lens 92 and third lens 93 are disposed on lens mount region 62. First lens 91 has a lens portion 91A. Second lens 92 has a lens portion 92A. Third lens 93 has a lens portion 93A. Surfaces of lens portions 91A, 92A, and 93A are the lens surfaces, respectively. In first lens 91, lens portion 91A and the region other than lens portion 91A are formed in one piece. In second lens 92, lens portion 92A and the region other than lens portion 92A are formed in one piece. In third lens 91, lens portion 93A and the region other than lens portion 93A are formed in one piece. The central axis of lens portions 91A, 92A, and 93A are the optical axis of lens portions 91A, 92A, and 93A, respectively. The optical axis of lens portions 91A, 92A, and 93A correspond to the optical axis of red laser diode 81, green laser diode 82, and blue laser diode 83, respectively. First lens 91, second lens 92 and third lens 93 convert the spot size of the light emitted from red laser diode 81, green laser diode 82 and blue laser diode 83, respectively. It is the shaping of the beam shape in a certain projection plane to a desired shape. First lens 91, second lens 92 and third lens 93 convert the spot size of the light emitted from red laser diode 81, green laser diode 82 and blue laser diode 83 so that the spot size of the light emitted from red laser diode 81, green laser diode 82 and blue laser diode 83 matches. With first lens 91, second lens 92 and third lens 93, each of the light emitted from red laser diode 81, green laser diode 82 and blue laser diode 83 is converted into collimated light.

First filter 97, second filter 98 and third filter 99 are placed on a filter mount region 63. First filter 97 is placed on a straight line connecting red laser diode 81 and first lens 91. Second filter 98 is placed on a straight line connecting green laser diode 82 and second lens 92. Third filter 99 is placed on a straight line connecting blue laser diode 83 and third lens 93. First filter 97, second filter 98 and third filter 99 have a flat-plate shape with a main surface parallel to each other. First filter 97, second filter 98, and third filter 99 have a rectangular shape (square shape) in terms of the thickness direction of the plate.

Red laser diode 81, lens portion 91A of first lens 91 and first filter 97 are aligned in a straight line (aligned in the Y-axis direction) along the emission direction of the light of red laser diode 81. Green laser diode 82, lens portion 92A of second lens 92 and second filter 98 are arranged in a straight line (aligned in the Y-axis direction) along the emission direction of the light of green laser diode 82. Blue laser diode 83, lens portion 93A of third lens 93 and third filter 99 are arranged in a straight line (aligned in the Y-axis direction) along the emission direction of the light of blue laser diode 83.

The emission direction of red laser diode 81, green laser diode 82 and blue laser diode 83 are parallel to each other. The main surfaces of first filter 97, second filter 98, and third filter 99 are inclined 45° with respect to the emission direction (Y-axis direction) of red laser diode 81, green laser diode 82, and blue laser diode 83, respectively.

Next, the specific configuration of first filter 97, second filter 98, and third filter 99 are described. First filter 97 includes a plate member 97A. First filter 97 has a dielectric multilayer film 97C constituting a face 97B on the side facing lens portion 91A (see FIG. 3). Dielectric multilayer film 97C is formed by stacking a plurality of films. First filter 97 reflects red light due to dielectric multilayer film 97C. Specifically, of the light incident on face 97B of first filter 97, dielectric multilayer film 97C reflects more than 90% of the light with a wavelength between 620 and 660 nm. Since first filter 97 is arranged at an angle of 45° to the emission direction of red laser diode 81, the incident angle of the red light is 45°. As an alternative to dielectric multilayer film 97C, for example, a deposited metal film, such as aluminum or silver, may be employed.

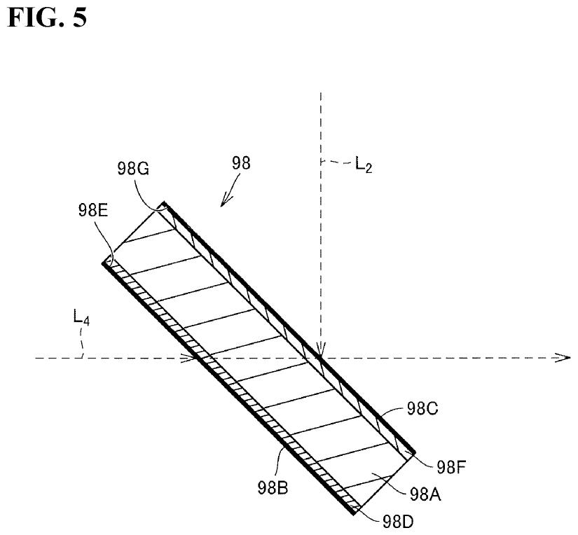

Next, the configuration of second filter 98 is described. FIG. 5 is an enlarged cross-sectional view of second filter 98 in first embodiment. FIG. 5 shows a cross-sectional view of second filter 98 when cut in the X-Y plane. Referring to FIG. 5, second filter 98 includes a plate member 98A including a light transmitting member. Second filter 98 includes a first face 98B and a second face 98C. Second filter 98 is disposed on filter mount region 63 such that first face 98B faces toward first filter 97 and second face 98C faces toward third filter 99. Red light, which is the first light emitted from red laser diode 81 and reflected in face 97B of first filter 97, enters first face 98B.

Second filter 98 includes a first dielectric multilayer 98D constituting a first face 98B. First dielectric multilayer 98D includes a film 98E having polarization selectivity that selectively transmits the light of the p-polarized light component, which is the light of the linearly polarized light component in a particular direction contained in the red light. Specifically, in film 98E, the transmittance of the p-polarized light component of the red light is 95% or more and the transmittance of the light of the s-polarized light component, which is the light of linearly polarized light component in other than a specific direction, is 5% or less. Film 98E may include a plurality of layers or may be a single layer. Film 98E may be disposed on the front side of first face 98B or may be disposed inside first dielectric multilayer 98D. By including such a film 98E, second filter 98 has a polarization selectivity that selectively transmits light of linearly polarized light components in a particular direction in the red light.

Second filter 98 includes a second dielectric multilayer 98F constituting a second surface 98C. Both the light transmittance of the p-polarized light component and the light transmittance of the s-polarized light component of the red light of second dielectric multilayer 98F are 95% or more. Second dielectric multilayer film 98F includes a film 98G that reflects the second light, green light. Specifically, the reflectance in film 98G of the second light, the green light wavelength of 500-550 nm, is 95% or more. Film 98G may include a plurality of layers or may be a single layer. Film 98G may be disposed on the front side of second face 98C or inside second dielectric multilayer 98F. By including second dielectric multilayer film 98F and first dielectric multilayer film 98D including such a film 98G, second filter 98 has a wavelength selectivity that transmits red light and reflects green light.

Third filter 99 includes a plate member 99A including a member that transmits light. Third filter 99 includes a first face 99B and a second face 99C. Third filter 99 is disposed on filter mount region 63 such that first face 99B faces toward second filter 98 and second side 99C faces toward an emission window 42. The red light emitted from second face 98C of second filter 98 enters first face 99B. Green light emitted from green laser diode 82 and reflected in second face 98C of second filter 98 is incident on first face 99B.

Third filter 99 includes a first dielectric multilayer 99D constituting first face 99B. Both the light transmittance of the p-polarized light component and the light transmittance of the s-polarized light component of the red light of first dielectric multilayer 99D are 95% or more. The green light transmittance of first dielectric multilayer 99D is 95% or more.

Third filter 99 includes a second dielectric multilayered film 99E constituting second face 99C. Both the light transmittance of the p-polarized light component and the light transmittance of the s-polarized light component of the red light of second dielectric multilayer 99E are 95% or more. The green light transmittance of second dielectric multilayer 99E is 95% or more. Second dielectric multilayer film 99E reflects a third light, blue light. Specifically, it reflects 95% or more of the light in the 430-470 nm wavelength, which is the wavelength of the third light, blue light.

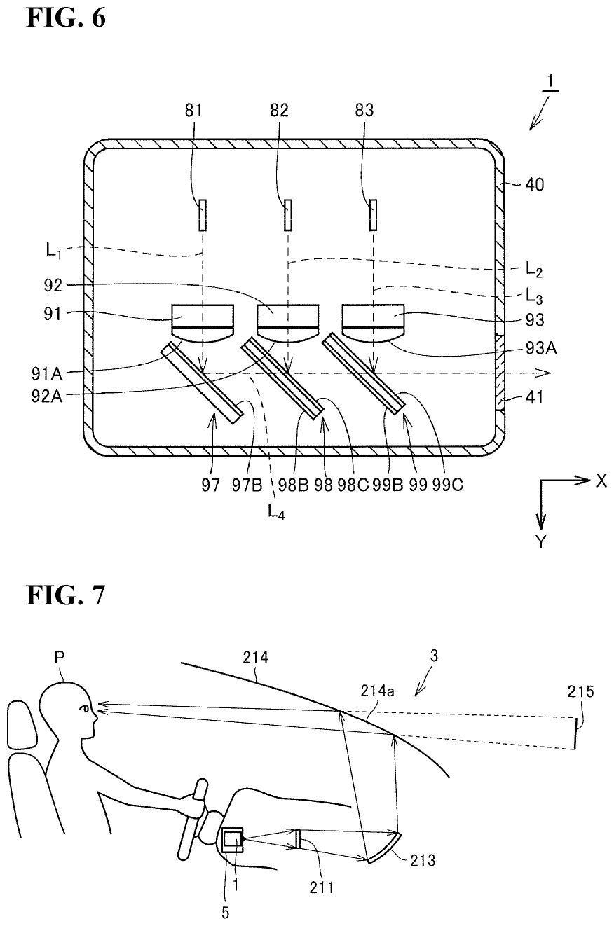

Next, the operation of the optical module 1 in the present embodiment is described. FIG. 6 shows a simplified representation of red laser diode 81, green laser diode 82, blue laser diode 83, first lens 91, second lens 92, third lens 93, and first filter 97, second filter 98, and third filter 99, which are arranged in optical module 1 in the first embodiment.

Referring in conjunction with FIG. 6, the red light is described. The red light emitted from red laser diode 81 travels along the optical path L₁. This red light enters lens portion 91A of first lens 91 and is converted to spot size of light. Specifically, for example, the red light emitted from red laser diode 81 is converted into collimated light. The red light, whose spot size is converted in first lens 91, travels along the light path L₁ and enters first filter 97. In this case, the incidence is on first face 97B of first filter 97. In this case, the incidence angle of the red light is 45° because first face 97B is inclined at 45° to the light path L₁.

Since first filter 97 reflects 90% or more of the red light due to dielectric multilayer film 97C formed on first face 97B, the light emitted from red laser diode 81 is mostly reflected by first face 97B and travels further along the optical path L₄. The red light then enters second filter 98. In this case, the red light is incident on second filter 98 through first face 98B contained in second filter 98. In this case, the incidence angle of the red light is 45° because first face 98B is inclined at 45° to the light path L₄.

Second filter 98 includes a first dielectric multilayer film 98D constitute first face 98B. First dielectric multilayer film 98D includes a film 98E having polarization selectivity that selectively transmits the light of the p-polarized light component, which is the light of the linearly polarized light component in a particular direction contained in the first light. Thus, for the red light incident from first face 98B of second filter 98, 95% or more of the light of the p-polarized light component is transmitted. The light transmittance of the s-polarized light component is 5% or less. That is, of the red light, most of the light of the p-polarized light component is transmitted through second filter 98 and most of the light of the s-polarized light component is cut off.

The red light, which most of the light of the p-polarized light component is transmitted and most of the light of the s-polarized light component cut off, passes through second filter 98. Second filter 98 includes a second dielectric multilayer 98F constitute a second surface 98C. Both the light transmittance of the p-polarized light component and the light transmittance of the s-polarized light component of second dielectric multilayer 98F are 95% or more. Thus, the red light is emitted from second face 98C with little or no cut off. The red light travels further along the optical path L₄ and enters third filter 99. In this case, the red light is incident on third filter 99 through first face 99B contained in third filter 99.

Third filter 99 includes a first dielectric multilayer 99D constituting first face 99B. Both the light transmittance of the p-polarized light component and the light transmittance of the s-polarized light component in the red light of first dielectric multilayer 99D are 95% or more. Thus, the red light is transmitted through third filter 99 with little or no cut off. Third filter 99 includes a second dielectric multilayer 99E constituting second face 99C. Both the light transmittance of the p-polarized light component of the red light of second dielectric multilayer 99E and the light transmittance of the s-polarized light component are 95% or more. Thus, the red light is emitted from second face 99C with little or no cut off. The red light travels further along the optical path L₄ and emits out of optical module 1 through glass member 41 fitted into emission window 42 of cap 40.

Next, the green light is described. The green light emitted from green laser diode 82 travels along the optical path L₂. This green light enters lens portion 92A of second lens 92 and the spot size of the light is converted. Specifically, for example, the green light emitted from green laser diode 82 is converted into collimated light. The green light whose spot size has been converted in second lens 92 travels along the optical path L₂ and enters second filter 98. In this case, the green light is incident on second filter 98 through second face 98C.

Second filter 98 includes a second dielectric multilayer 98F constituting second face 98C. Second dielectric multilayer film 98F includes a film 98G having wavelength selectivity that reflects the second light, green light. Therefore, 95% or more of the green light incident through second face 98C of the second filter 98 is reflected. Thus, the green light is reflected with little transmission and is emitted from the second face 98C. The green light travels further along the optical path L₄. Here, the red light emitting from second face 98C and traveling along the light path L₄ and the green light emitting from second face 98C and traveling along the light path L₄ are multiplexed.

The green light emitted from second face 98C is incident on third filter 99. In this case, the green light is incident on third filter 99 through first face 99B contained in third filter 99. Third filter 99 includes first dielectric multilayer 99D constituting first face 99B. The green light transmittance of first dielectric multilayer 99D is 95% or more. Therefore, the green light passes through the third filter 99 with little to no cutoff. Third filter 99 includes second dielectric multilayer 99E constituting second face 99C. The green light transmittance of second dielectric multilayer 99E is 95% or more. Thus, the green light is emitted from second face 99C with little or no cut off. The green light travels further along the optical path L₄ and emits out of optical module 1 through glass member 41 fitted into emission window 42 of cap 40.

Next, the blue light is described. The blue light emitted from blue laser diode 83 travels along optical path L₃. This blue light enters lens portion 93A of third lens 93 and the spot size of the light is converted. Specifically, for example, the blue light emitted from blue laser diode 83 is converted into collimated light. The blue light whose spot size has been converted in third lens 93 travels along the optical path L₃ and enters third filter 99. In this case, the blue light is incident on third filter 99 through second surface 99C.

Third filter 99 includes second dielectric multilayer film 99E constituting second face 99C. Second dielectric multilayer film 99E has wavelength selectivity to reflect a third light, blue light. Therefore, 95% or more of the blue light incident from second face 99C of third filter 99 is reflected. Therefore, the blue light is reflected with little transmission and is emitted from second face 99C. The blue light travels further along the optical path L₄. Here, the red light and the green light that emits from second face 99C and travels along the light path L₄ and the blue light that emits from the second face 99C and travels along the light path L₄ are multiplexed. The blue light is emitted out of optical module 1 through glass member 41 fitted into emission window 42 of cap 40.

In this way, the light formed by the multiplexing of red, green and blue light (multiplexed light) is emitted from optical module 1 along the optical path L₄. For example, the emitted light is injected into the MEMS (Micro Electro Mechanical Systems) located outside optical module 1. The MEMS scans by reflecting light into mirrors that rocks periodically at high speed in one direction (horizontal) and in a direction perpendicular to one direction (vertical). The multiplexed light emitted from optical module 1 is reflected by the rocking mirror and scanned to draw characters and figures.

Second filter 98 provided in optical module 1 has a wavelength selectivity that transmits the first light, red light, and reflects the second light, green light. Therefore, by arranging first laser diode 81, second laser diode 82 and second filter 98 so that the light path L₄ of the red light emitted through second filter 98 and the light path L₄ of the green light reflected through second filter 98 are the same, the red light and the green light can be multiplexed. In the present embodiment, since the laser diode 83, third filter 99, and the like are included, the red light, green light, and the blue light can be multiplexed. Second filter 98 has polarization selectivity that selectively transmits light of the p-polarized light component, which is light of the linearly polarized light component in a particular direction in the red light. Therefore, the intensity of the red light can be adjusted by reducing the effect of the light of the s-polarized light component. The s-polarized light is a linearly polarized light component of the red light other than in a specific direction emitted from second filter 98. Therefore, the intensity ratio of red light to green light and even to blue light in the multiplexing light can be adjusted appropriately. Since second filter 98 has a polarization selectivity that selectively transmits light of linearly polarized light components in a particular direction in the red light, there is no need to install a new polarizer in optical module 1. Therefore, such an optical module 1 can be made smaller. Optical module 1 can precisely adjust the brightness and color tone of the multiplexing light.

In the present embodiment, second filter 98 includes first face 98B where red light enters, second face 98C where red light incident from first face 98B emits and green light reflects, first dielectric multilayer film 98D including first face 98B, and second dielectric multilayer film 98F including second face 98C. First dielectric multilayer film 98D includes film 98E having polarization selectivity that selectively transmits light of the p-polarized light component, which is light of the linearly polarized light component in a particular direction included in the red light, and second dielectric multilayer film 98F includes film 98G having wavelength selectivity that reflects the green light. Second filter 98 can reduce the difference between the thickness of dielectric multilayer film 98D constituting first face 98B and the thickness of dielectric multilayer film 98F formed on second face 98C. Therefore, the warping of second filter 98 caused by the difference in thickness of the dielectric multilayer film 98D, 98F can be reduced. Therefore, the brightness and color tone of the multiplexing light can be adjusted more precisely.

In the present embodiment, the angle of incidence of the red light to first face 98B is 45°, and is in a range of between 10° and 60°. At such an angle of incidence, there is a large difference between the reflectance of the light of the linearly polarized light component in a particular direction, for example, the p-polarized light component, and the reflectance of the light of the linearly polarized light component in other directions, for example, the s-polarized light component. Therefore, it is relatively easy to form film 98E with polarization selectivity. Therefore, second filter 98 with polarization selectivity can be produced efficiently.

In the present embodiment, the second filter 98 has transmittance of 90% or more of the p-polarized light component in the red light and transmittance of 10% or less of the s-polarized light component in the red light. Specifically, second filter 98 has transmittance of 95% or more of the p-polarized light component in the red light and transmittance of 5% or less of the s-polarized light component in the red light. Therefore, the linearly polarized light component of the red light in a particular direction can be used as the p-polarized light component to reduce the optical loss and to adjust the multiplexing light efficiently.

In the present embodiment, second filter 98 reflects 90% or more of the green light emitted from green laser diode 82, thus allowing the green light to be used efficiently.

In the present embodiment, optical module 1 includes first lens 91, second lens 92 and third lens 93 which convert the spot size of light emitted from red laser diode 81, green laser diode 82 and blue laser diode 83, respectively. Thus, light with a desired spot size can be emitted from optical module 1.

In the present embodiment, the plurality of laser diodes include red laser diode 81 that emits red light, green laser diode 82 that emits green light, and blue laser diode 83 that emits blue light. In this way, these lights can be multiplexed to form a light of the desired color. In particular, red light shows a large change in the polarization angle with respect to the output. Therefore, by adopting the above configuration, the brightness and color tone of the multiplexing light can be precisely adjusted by reducing the effect of the change in polarization angle when the light is output in optical module 1.

In the present embodiment, a light-receiving device is arranged outside optical module 1 to receive the multiplexed light. Optical module 1 controls the output of each laser diode by monitoring the intensity of the light with the light-receiving device described above, and adjusts the brightness and color tone of the merged light precisely.

Such an optical module 1 can be used effectively for the HUD for vehicles. Next, a case in which optical module 1 of the present embodiment is used as a light source of a HUD system installed in an automobile is described. FIG. 7 is a schematic diagram showing an example of a HUD system installed in an automobile.

Referring to FIG. 7, a HUD system 3 includes a MEMS 5 including optical module 1, a diffuser 211, a magnifying glass 213, and a windshield 214. MEMS 5 includes a mirror that rocks periodically at high speed in one direction (horizontal) and in a direction perpendicular to one direction (vertical). The multiplexed light emitted from optical module 1, for example, the multiplexed of red light, green light and blue light, is reflected by the mirror that rocks periodically at high speed in one direction (horizontal direction) and in a direction perpendicular to one direction (vertical direction), and scanned to project an image. The image projected from MEMS 5 is formed on the surface of diffuser 211 as an intermediate image. The intermediate image is magnified by magnifying glass 213 and projected onto display area 214a of windshield 214. The image projected onto display area 214a is reflected by windshield 214 and a virtual image 215 is formed at the back of windshield 214 as viewed from the driver P of windshield 214. The driver P can see virtual image 215 as if the image is displayed on the side of windshield 214 where virtual image 215 is located.

According to optical module 1 in the first embodiment, the intensity and color tone of the multiplexed light can be adjusted precisely, and thus a high-precision image can be projected. This is particularly useful in HUD system 3 described above, where the multiplexed light enters windshield 214 at a large angle of incidence, because it reduces the effect on the light intensity ratio based on the difference between the reflectance of the light of the p-polarized light component of the red light and the reflectance of the light of the s-polarized light component of the red light. In addition, the miniaturization of optical module 1 allows for effective use of space inside the vehicle.

### Second Embodiment

An optical module 1 of second embodiment has basically the same structure as in the first embodiment and has the same effect. However, optical module 1 in the second embodiment differs from the case of the first embodiment in the following respects.

In second filter 98 provided with optical module 1 in the first embodiment, first dielectric multilayer film 98D includes film 98E having polarization selectivity and second dielectric multilayer film 98F includes film 98G having wavelength selectivity. In second filter 98 provided in optical module 1 in the second embodiment, second dielectric multilayer film 98F includes film 98E having polarization selectivity and film 98G having wavelength selectivity.

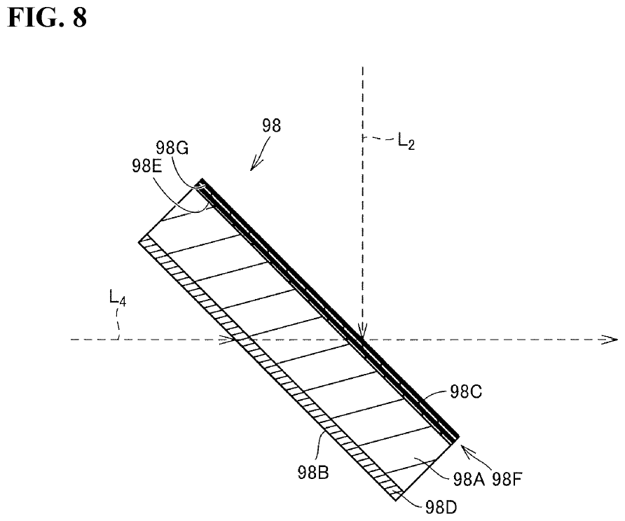

FIG. 8 is a cross-sectional view of the second filter in the second embodiment. Referring to FIG. 8, second filter 98 includes second dielectric multilayer film 98F constituting second face 98C, with film 98E having polarization selectivity and film 98G having wavelength selectivity. Film 98G with wavelength selectivity is located on second face 98C side than film 98E with polarization selectivity. Second filter 98 includes second dielectric multilayer film 98F constituting second face 98C with a film 98G having wavelength selectivity and a film 98E having polarization selectivity. Therefore, the total deposition time in forming first dielectric multilayer film 98D and second dielectric multilayer film 98F during the manufacturing of second filter 98 can be reduced.

In the second embodiment, any of dielectric multilayer films 99D, 99E included in third filter 99 may be made to have polarization selectivity. That is, first dielectric multilayer film 99D provided in third filter 99 may include film 98E having polarization selectivity, and second dielectric multilayer film 99E provided in third filter 99 may include film 98E having polarization selectivity. In this case, since third filter 99 has polarization selectivity that selectively transmits the light of the p-polarized light component, which is light of the linearly polarized light component in a particular direction in the red light, third filter 99 can adjust the intensity of the red light by reducing the effect of the light of the s-polarized light component, which is the linearly polarized light component of the red light in a direction other than the particular direction emitted from third filter 99. Therefore, the intensity ratio of red light, green light and blue light in the multiplexing light can be adjusted appropriately. Therefore, such an optical module 1 can precisely adjust the brightness and color tone of the multiplexed light while maintaining a compact size.

### Third Embodiment

An optical module 1 of the third embodiment has basically the same structure as in the first embodiment and has the same effect. However, optical module 1 in the second embodiment differs from the case of the first embodiment in the following respects.

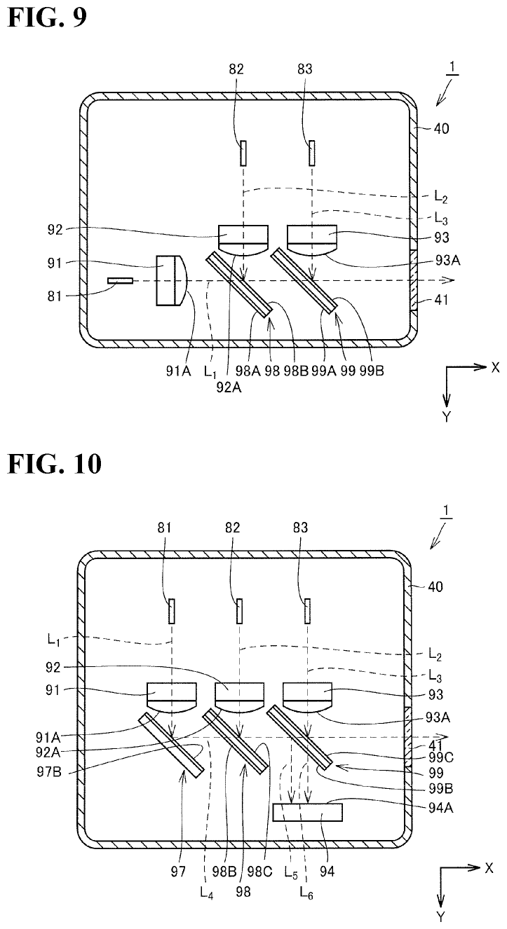

In the first embodiment, the emission direction of the red light emitted from the red laser diode, the emission direction of the green light emitted from the green laser diode, and the emission direction of the blue light emitted from the blue laser diode are all set to the same direction (Y-axis direction). In the third embodiment, the emission direction of the red light emitted from the red laser diode, the emission direction of the green light emitted from the green laser diode and the emission direction of the blue light emitted from the blue laser diode are changed. FIG. 9 is a simplified view of red laser diode 81, green laser diode 82, blue laser diode 83, first lens 91, second lens 92, third lens 93, and first filter 97, second filter 98, and third filter 99, which are arranged in optical module 1 in the third embodiment.

Referring to FIG. 9, the emission direction of the red light emitted from red laser diode 81 shall be orthogonal to the emission direction of the green light emitted from green laser diode 82 and the emission direction of the blue light emitted from blue laser diode 83. Specifically, the emission direction of the red light emitted from red laser diode 81 is the X-axis direction, the emission direction of the green light emitted from green laser diode 82 and the emission direction of the blue light emitted from blue laser diode 83 are the Y-axis direction.

According to the configuration, first filter 97 can be omitted. Therefore, the number of components of optical module 1 can be reduced.

### Fourth Embodiment

An optical module 1 of the fourth embodiment has basically the same structure as in the first embodiment and has the same effect. However, optical module 1 in the fourth embodiment differs from the case of the first embodiment in the following respects.

FIG. 10 is a simplified view of red laser diode 81, green laser diode 82, blue laser diode 83, the first lens 91, second lens 92, third lens 93, and first filter 97, second filter 98, and third filter 99, which are arranged in optical module 1 in the fourth embodiment. Referring to FIG. 10, optical module 1 includes a photodiode 94 as a light-receiving device. Photodiode 94 includes a light-receiving portion 94A. Blue laser diode 83, lens portion 93A of third lens 93, third filter 99 and light-receiving portion 94A of photodiode 94 are arranged in a straight line (aligned in the Y-axis direction) along the emission direction of the light of blue laser diode 83. In the present embodiment, third filter 99 transmits most of the red and green light in first face 99 Band reflects some of them. Third filter 99 reflects most of the blue light and transmits some of it. That is, some of the red and green light that reaches third filter 99 is reflected in third filter 99 and travels along the light path L5 to light-receiving portion 94A of photodiode 94. Some of the blue light that reaches third filter 99 passes through third filter 99 and travels along the light path L6 to light-receiving portion 94A of photodiode 94. The current values flowing to red laser diode 81, green laser diode 82 and blue laser diode 83 are then adjusted based on the information of the intensity of the red, green and blue light received in photodiode 94. In the present embodiment, red laser diode 81, green laser diode 82 and blue laser diode 83 can be controlled by an auto power control (APC) drive. In this way, strict control of red laser diode 81, green laser diode 82, and blue laser diode 83 can be performed. Based on the output of the light received by photodiode 94, the output of red laser diode 81, green laser diode 82, and blue laser diode 83 can be adjusted appropriately. According to the present embodiment, the intensity ratio of the light to be multiplexed can be appropriately adjusted when feeding back to the output of red laser diode 81, green laser diode 82, and blue laser diode 83 based on the intensity of the light received by photodiode 94. Therefore, it is easy to precisely adjust the brightness and color tone of the multiplexing light.

In optical module 1 in the present embodiment, photodiode 94 receives light that is multiplexed by third filter 99. Therefore, photodiode 94 receives the light of the p-polarized light component, which is the light of the linearly polarized light component in a particular direction that is selectively transmitted for red light. When feedback to the output of red laser diode 81 based on the intensity of the light received by photodiode 94, the intensity ratio of the multiplexed light can be adjusted appropriately. In adjusting the intensity ratio of each light component of the multiplexed light, the effect of the light of the s-polarized light component can be reduced. Therefore, it is easy to precisely adjust the brightness and color tone of the multiplexing light.

In the above embodiments, the case in which light from three laser diodes is multiplexed is described. However, optical module 1 may include two laser diodes or four or more laser diodes. In the above embodiments, the case where a wavelength-selective filter is employed as first filter 97, second filter 98 and third filter 99 is illustrated. However, these filters may be, for example, polarization synthesis filters.

In the above embodiments, optical module 1 includes electronic temperature control module 30. However, for example, optical module 1 does not need to include electronic temperature control module 30 when used in environments with small temperature changes.

The embodiments disclosed herein are illustrative in all respects and should be understood as constituting non-limitative in any perspective. The scope of the present disclosure is defined by the claims rather than by the description above. The scope of the present disclosure is intended to embrace all changes within the meaning and range of equivalency of the claims.

### REFERENCE SIGNS LIST

1 optical module, 2 protective member, 3 HUD system, 4 base member, 5 MEMS, 10 base portion, 10A, 10B, 60A main surface, 20 light-forming portion, 30 electronic temperature control module, 31 heat absorption plate, 32 heat dissipation plate, 33 semiconductor pillar, 40 cap, 41 glass member, 42 emission window, 51 lead pin, 60 laser diode base, 61 chip mount region, 62 lens mount region, 63 filter mount region, 71 first sub-mount, 72 second sub-mount, 73 third sub-mount, 81 red laser diode, 82 green laser diode, 83 blue laser diode, 91 first lens, 92 second lens, 93 third lens, 91A, 92A, 93A lens portion, 94 photodiode, 94A light-receiving portion, 97 first filter, 98 second filter, 99 third filter, 97A, 98A, 99A plate member, 97B face, 98B, 99B first face, 98C, 99C second face, 97C dielectric multilayer film, 98D, 99D first dielectric multilayer film, 98F, 99F second dielectric multilayer film, 98E, 98G film, 100 thermistor, 211 diffuser, 213 magnifying glass, 214 windshield, 214a display area

1. An optical module comprising:
a first laser diode configured to emit a first light;
a second laser diode configured to emit a second light of a different wavelength from the first light; and
a filter configured to multiplex the first light and the second light,
wherein the filter has polarization selectivity for selectively transmitting linearly polarized light component of the first light in a particular direction and wavelength selectivity for transmitting the first light and reflecting the second light.

2. The optical module of claim 1, wherein the filter includes a first face into which the first light configured to enter, a second face from which a first light incident from the first face configured to emit and from which the second light configured to reflect, a first dielectric multilayer film constituting the first face, and a second dielectric multilayer film constituting the second face,
wherein the first dielectric multilayer film has the polarization selectivity that selectively transmits light of linearly polarized light component in a particular direction contained in the first light, and the second dielectric multilayer film has the wavelength selectivity that reflects the second light.

3. The optical module of claim 1, wherein the filter includes a first face into which the first light configured to enter, a second face from which a first light incident from a first face configured to emit and from which the second light configured to reflect, and a second dielectric multilayer film constituting the second face,
wherein the second dielectric multilayer film has the polarization selectivity that selectively transmits light of a linearly polarized light component in a particular direction contained in the first light, and the wavelength selectivity that reflects the second light.

4. The optical module of claim 2, wherein an incident angle of the first light to the first face is from 10 degree to 60 degree.

5. The optical module of claim 1, wherein the filter has transmittance of 90% or more of a p-polarized light component in the first light and transmittance of 10% or less of a s-polarized light component in the first light.

6. The optical module of claim 1, wherein the filter reflects 90% or more of the second light emitted from the second laser diode.

7. The optical module of claim 1, further comprising a light-receiving device receiving the light multiplexed by the filter.

8. The optical module of claim 1, further comprising a lens converting spot size of at least one of the first light and the second light.

9. The optical module of claim 1, further comprising a protective member surrounding the first laser diode, the second laser diode and the filter and sealing the first laser diode, the second laser diode and the filter.

10. The optical module of claim 1, further comprising a third laser diode configured to emit blue light, wherein the first laser diode configured to emit red light and the second laser diode configured to emit green light.
